(19) United States
(12) Patent Application Publication
(10) Pub. No.: US 2008/0304217 A1
(43) Pub. Date: Dec. 11, 2008

(54) PORTABLE ELECTRONIC DEVICE

(75) Inventors: Chin-Chung Lai, Taipei (TW); Hsiao-Feng Li, Taipei (TW)

Correspondence Address: Muncy, Geissler, Olds & Lowe, PLLC, P.O. BOX 1364, FAIRFAX, VA, 22038-1364, US

(73) Assignee: ASUSTeK COMPUTER INC.

(21) Appl. No.: 12/121,157

(22) Filed: May 15, 2008

(30) Foreign Application Priority Data
Jun. 5, 2007 (TW) 096120206

(51) Int. Cl. H05K 5/02

(52) U.S. Cl. 361/681

(57) ABSTRACT

A portable electronic device includes a first body, a second body and a guiding assembly. The first body is disposed adjacently to the second body. The second body has a groove with a positioning portion. The guiding assembly has a guiding part fixed at the first body. The guiding part has a guiding portion slidingly disposed at the groove to allow the second body to slide relatively to the first body. When the guiding portion slides to the positioning portion, the second body is capable of rotating relatively to the first body, and the guiding portion is allowed to be fastened in the positioning portion. Thus, an angle is formed between the second body and the first body.

### CROSS REFERENCE TO RELATED APPLICATIONS

This Non-provisional application claims priority under 35 U.S.C. §119(a) on Patent Application No(s). 096120206 filed in Taiwan, Republic of China on Jun. 5, 2007, the entire contents of which are hereby incorporated by reference.

### BACKGROUND OF THE INVENTION

1. Field of Invention

The invention relates to an electronic device and, more particularly, to a portable electronic device.

2. Related Art

The portable electronic device not only has advantages such as lightness, slimness, shortness, smallness and convenience in carrying, but also has a special man-machine interface (such as touch input interface) and functions such as wireless communication function (such as audio and data transfer function) and human intelligence function (such as word and audio recognition function). Therefore, the portable electronic device is widely used in various fields. The ultra mobile personal computer (UMPC), the translator, the personal digital assistant (PDA), the notebook computer, the audio and video player or handheld game player is the common portable electronic device. Taking the UMPC as an example, an UMPC has functions such as making or answering a phone call, accessing Internet, wirelessly transmitting, taking a picture, using GPS positioning device, compiling and programming and playing music and game.

FIG. 1 is a schematic diagram showing a conventional flip type electronic device 1, and FIG. 2 is a schematic diagram showing a conventional sliding type electronic device 2. For example, the flip type electronic device 1 is a notebook. The sliding electronic device 2 is an UMPC. Both of the flip type electronic device 1 and the sliding type electronic device 2 have first bodies 11 and 21 and second bodies 12 and 22, respectively, and the first bodies 11 and 21 are disposed adjacently to the second bodies 12 and 22, respectively.

In FIG. 1A, the flip type electronic device 1 further has a pivot 13, and the first body 11 and the second body 12 are pivotally connected to the pivot 13. The second body 12 rotates relatively to the first body 11 with the pivot 13 as the axis. In FIG. 2, each of two sides of a surface 211 of the first body 21 has a groove 212 along the direction of the Y axis. A surface 221 of the second body 22 has a protrudent block (not shown) whose position is corresponding to the position of each groove 212. Thus, the second body 22 may be slidingly provided at the first body 21. Herein, the each of the first bodies 11 and 21 may be a keyboard module or a control module, and each of the second bodies 12 and 22 may be a display panel or a touch pad. The first bodies 11 and 21 are used to the control the operation of the second bodies 12 and 22.

However, in the flip type electronic device 1, the pivot 13 is easily destroyed because of overuse, and a rotating room should be prepared to allow the second body 12 to rotate relatively to the first body 11 in the flipping process. The sliding type electronic device 2 does not have above defects. However, the first body 21 and the second body 22 of the sliding type electronic device 2 are parallel, and therefore, it is used inconveniently. In addition, after using for a long time, users may feel uncomfortable because of incorrect usage pose. The above design does not accord with ergonomics.

### SUMMARY OF THE INVENTION

The objective of the invention is to provide a portable electronic device which is operated easily, does not occupy large room and accords with ergonomics.

To obtain the objective of the invention, the invention provides a portable electronic device including a first body, a second body and a guiding assembly. The first body is disposed adjacently to the second body. The second body has a groove. The groove has a positioning portion. The guiding assembly has a guiding part fixed at the first body. The guiding part has a guiding portion slidingly disposed at the groove to allow the second body to slide relatively to the first body. When the guiding portion slides to the positioning portion, the second body is capable of rotating relatively to the first body to fasten the guiding portion in the positioning portion. Thus, the second body forms an angle relatively to the first body.

According to a portable electronic device of the invention, when the second body slides relatively to the first body, and the guiding portion slides to the positioning portion, the second body is capable of rotating relatively to the first body, and then the guiding portion is allowed to be fastened in the positioning portion. Thus, the second body stands with an angle relatively to the first body. Compared with the conventional technology, the first body and the second body not only can partly separate from each other in a sliding mode, but also can open relatively to form an angle. Thus, the first body and the second body are provided at different planes, and the portable electronic device accords with ergonomics. The portable electronic device which is operated conveniently, does not occupy large room and accords with ergonomics is provided.

These and other features, aspects, and advantages of the present invention will become better understood with regard to the following description, appended claims, and accompanying drawings.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a conventional flip type electronic device;

FIG. 2 is a schematic diagram showing a conventional sliding type electronic device;

FIG. 3 is a schematic diagram showing a portable electronic device according to a preferred embodiment of the invention;

FIG. 4 is an exploded diagram showing a partial structure of a portable electronic device shown in FIG. 3;

FIG. 5A to FIG. 5C are schematic diagrams showing the structure of the positioning portion with different forms of the second body shown in FIG. 4; and

FIG. 6A to FIG. 6E are schematic diagrams showing the operation of the portable electronic device of a preferred embodiment of the invention.

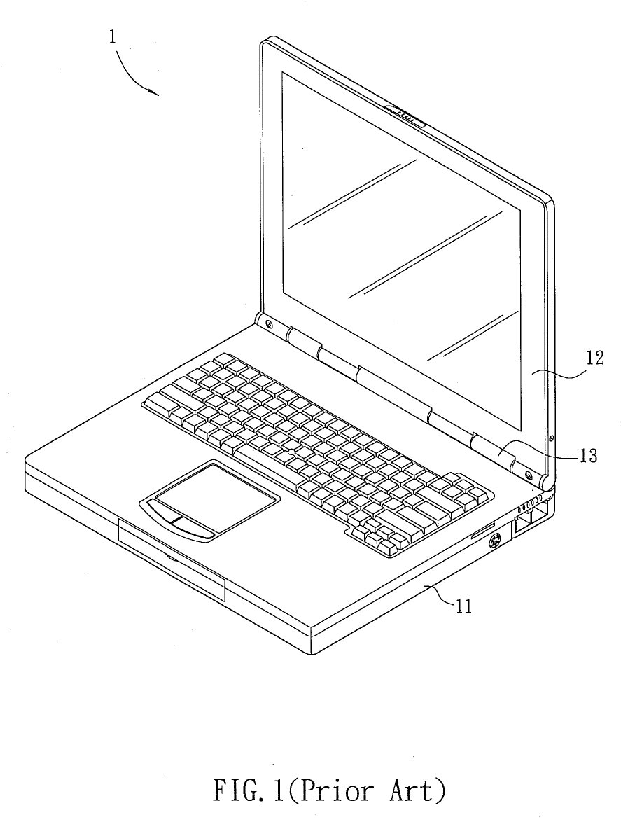

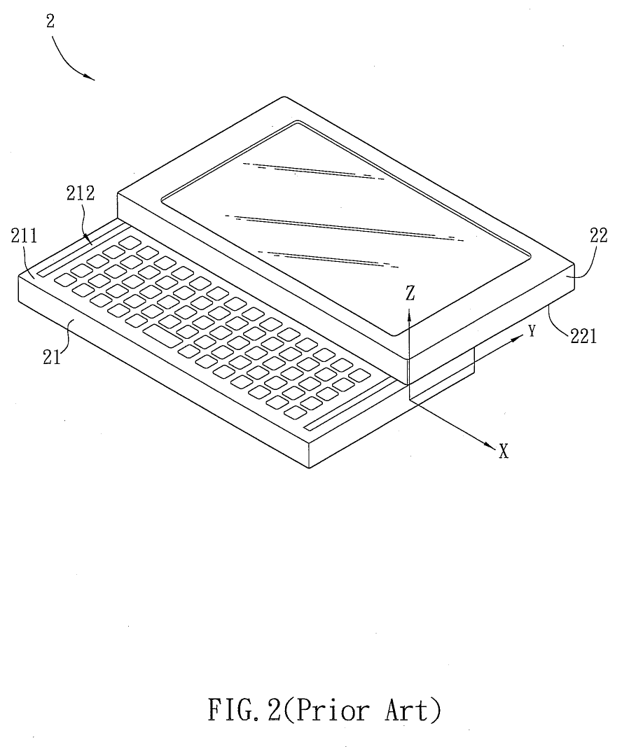

### DETAILED DESCRIPTION OF THE INVENTION

The present invention will be apparent from the following detailed description, which proceeds with reference to the accompanying drawings, wherein the same references relate to the same elements.

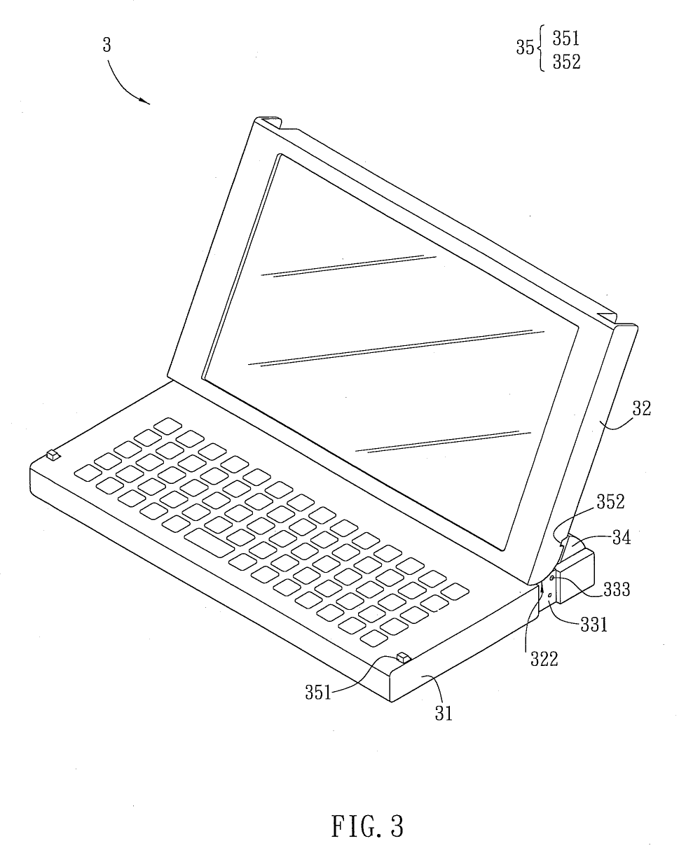

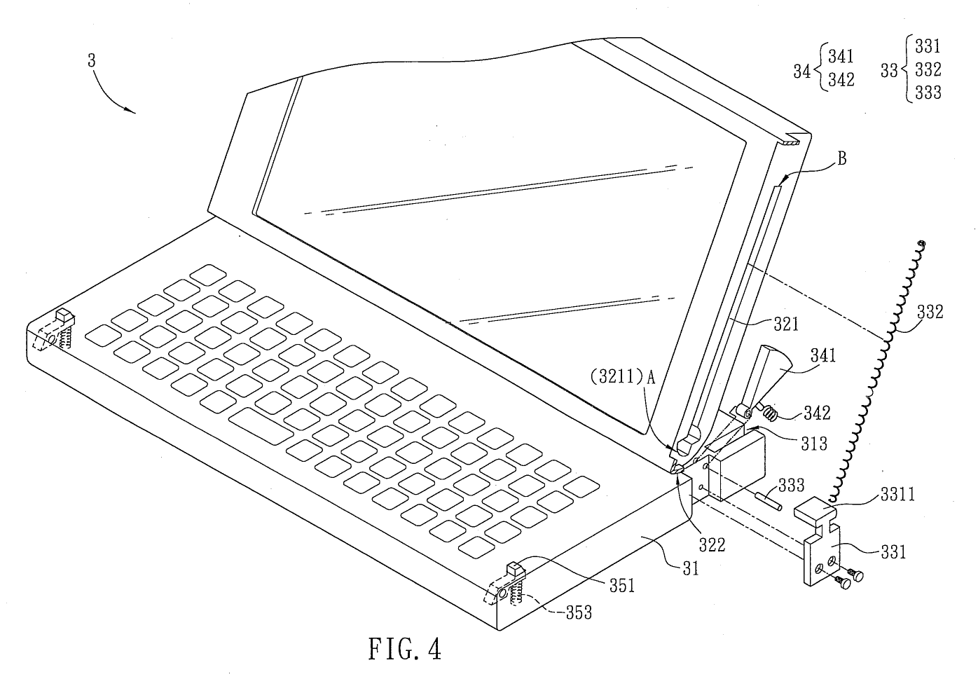

FIG. 3 is a schematic diagram showing a portable electronic device 3 of a preferred embodiment of the invention. FIG. 4 is an exploded diagram showing a partial structure of the portable electronic device 3 shown in FIG. 3. In the embodiment, the portable electronic device 3 includes a first body 31, a second body 32, a guiding assembly 33, an elastic assembly 34 and a clipping assembly 35, and the first body 31 is disposed adjacently to the second body 32. The portable electronic device 3 is one of a portable communication device, an ultra mobile personal computer, a personal digital assistant, a notebook, a multimedia player (such as MP3 or MP4) and a handheld game player.

The second body 32 has a groove 321 and a guiding angle 322. A first end A of the groove 321 is a positioning portion 3211. The groove 321 may be located at the shorter side or the longer side of the second body 32. The disposing position may be adjusted according to the actual need. The guiding angle 322 is disposed at the longer side of the second body 32 adjacent to the first end A to allow the second body 32 to rotate relatively to the first body 31 smoothly.

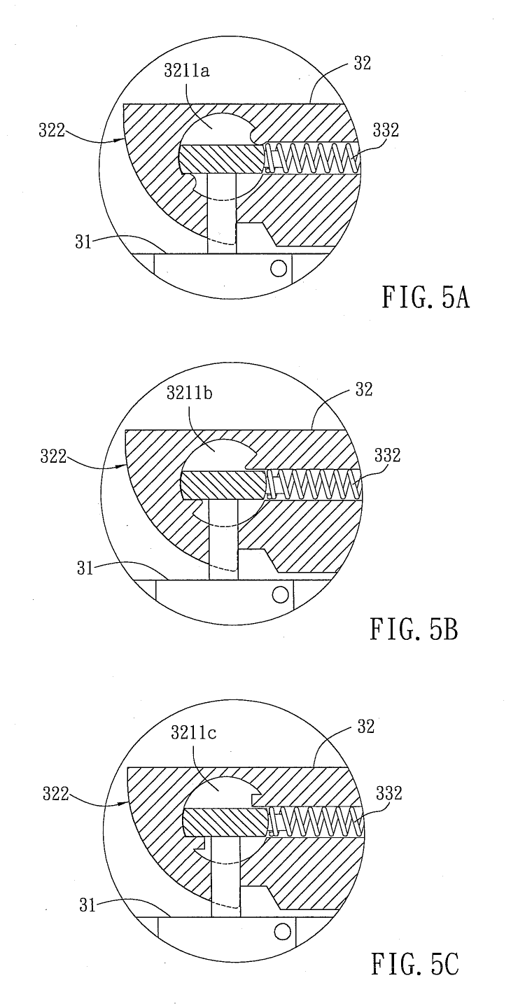

FIG. 5A to FIG. 5C are schematic diagrams showing the structure of the positioning portion 3211 with different forms of the second body 32 in FIG. 4. As shown in FIG. 4, FIG. 5A to FIG. 5C, the positioning portion 3211 may be a circular recess (as 3211a shown in FIG. 5A), a fan-shaped recess, a triangular recess (as 3211b shown in FIG. 5B), a pair of fan-shaped recesses, a pair of semi-circular recesses, a pair of triangular recesses or any recess with a symmetrical shape. In addition, one of the recess, recessed point, protrudent block (as 3211c shown in FIG. 5C), protrudent point, protrudent rib, wedge, tenon, stair-shaped structure and the sawtooth structure or any combination thereof may be disposed in the positioning portion 3211. In the embodiment, the positioning portion 3211 is a pair of fan-shaped recesses.

As shown in FIG. 3 and FIG. 4, the guiding assembly 33 has a guiding part 331 and a first elastic part 332. The guiding part 331 has a guiding portion 3311 slidingly provided at the groove 321 to allow the second body 32 to slide relatively to the first body 31. The first elastic part 332 is held in the groove 321, and the two ends of the first elastic part 332 are against the guiding portion 3311 and the second end B of the groove 321, respectively. The first elastic part 332 may be an extension spring, a compression spring, an elastic sheet or a telescopic sleeve. In the embodiment, the first elastic part 332 is a compression spring.

The elastic assembly 34 is disposed at a holding room 313 of the first body 31. In the embodiment, the elastic assembly 34 has an auxiliary part 341 and a second elastic part 342. The auxiliary part 341 and the second elastic part 342 may be held in the holding room 313 of the first body 31. The auxiliary part 341 is fixed in the holding room 313 via a pivot 333 of the guiding assembly 33. The second elastic part 342 is disposed between the first body 31 and the auxiliary part 341.

When the second body 32 rotates relatively to the first body 31, the auxiliary part 341 of the elastic assembly 34 is affected by the resilience generated by the compressed second elastic part 342. Thus, the auxiliary part 341 provides a force to the second body 32 relatively to the first body 31 to allow the second body 32 to rotate relatively to the first body 31 more smoothly and easily. The auxiliary part 341 may be one of the protrudent block, the fan-shaped block and the triangular block or any combination thereof. The second elastic part 342 may be an extension spring, a compression spring, an elastic sheet or a telescopic sleeve. In the embodiment, the auxiliary part 341 is a fan-shaped block, and the second elastic part 342 is a compression spring.

The clipping assembly 35 has a first clipping part 351 and a second clipping part 352. The first clipping part 351 and the second clipping part 352 may be fastened to each other. In the embodiment, the first clipping part 351 is disposed on the first body 31, and the second clipping part 352 is disposed on the second body 32. The first clipping part 351 is a hook or an indentation portion, and the second clipping part 352 is an indentation portion or a hook corresponding to the first clipping part 351 to allow the first body 31 and the second body 32 to abut against each other because of the fastening of the first clipping part 351 and the second clipping part 352.

In addition, the clipping assembly 35 further has a third elastic part 353 disposed between the first clipping part 351 and the first body 31 to allow the first clipping part 351 to be fastened with the second clipping part 352 more steadily. The third elastic part 353 may be an extension spring, a compression spring, an elastic sheet or a telescopic sleeve. In the embodiment, the first clipping part 351 is a hook, and the second clipping part 352 is an indentation portion corresponding to the first clipping part 351. The third elastic part 353 is a compression spring.

In the embodiment, a keyboard module, an input interface or a control interface may be disposed at the first body 31, and a display device such as a liquid crystal display panel, a touch panel or an organic light emitting panel may be disposed at the second body 32. The first body 31 is electrically connected to the second body 32, and the first body 31 controls the operation of the second body 32.

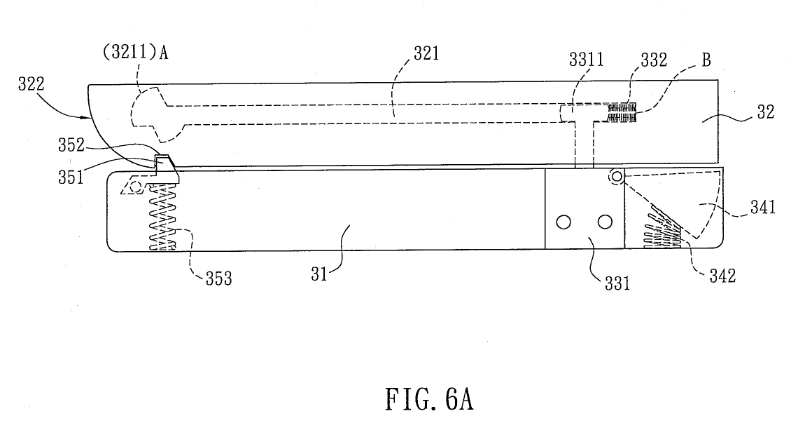

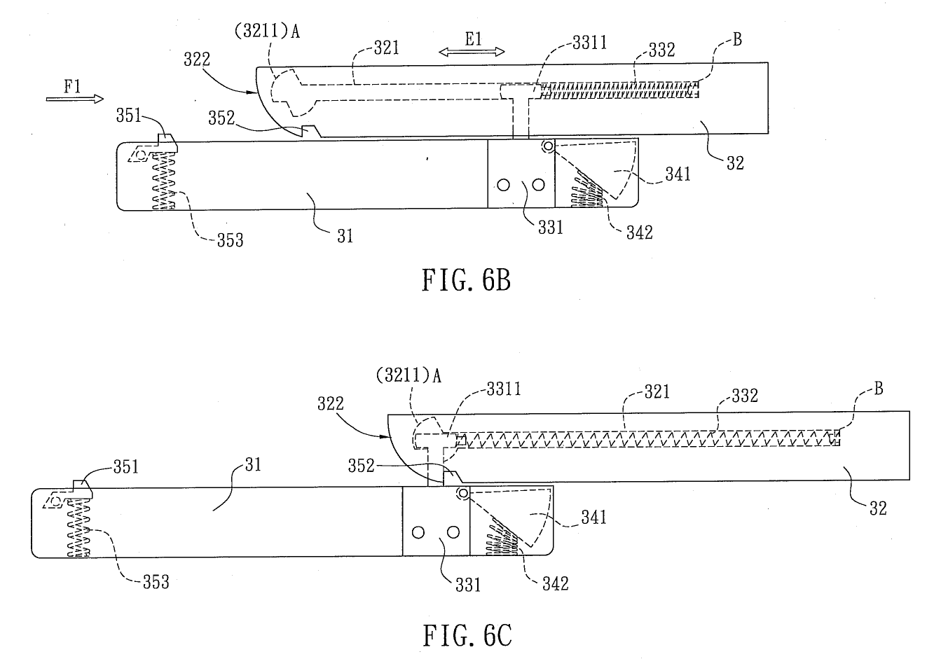

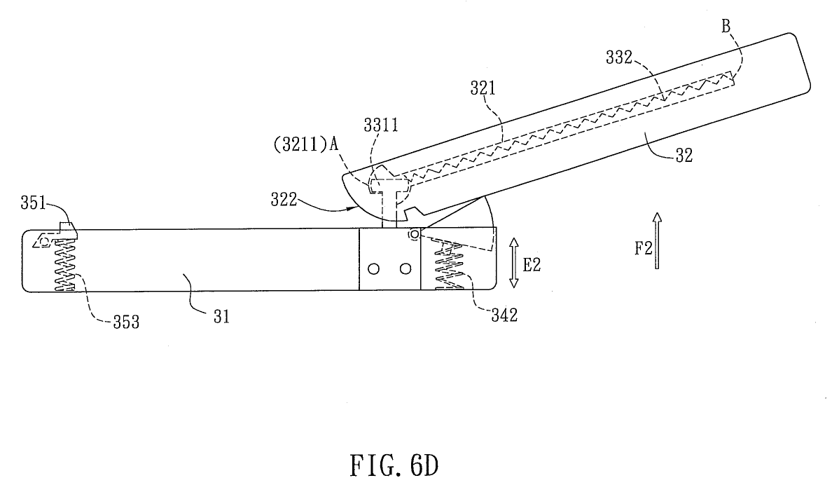

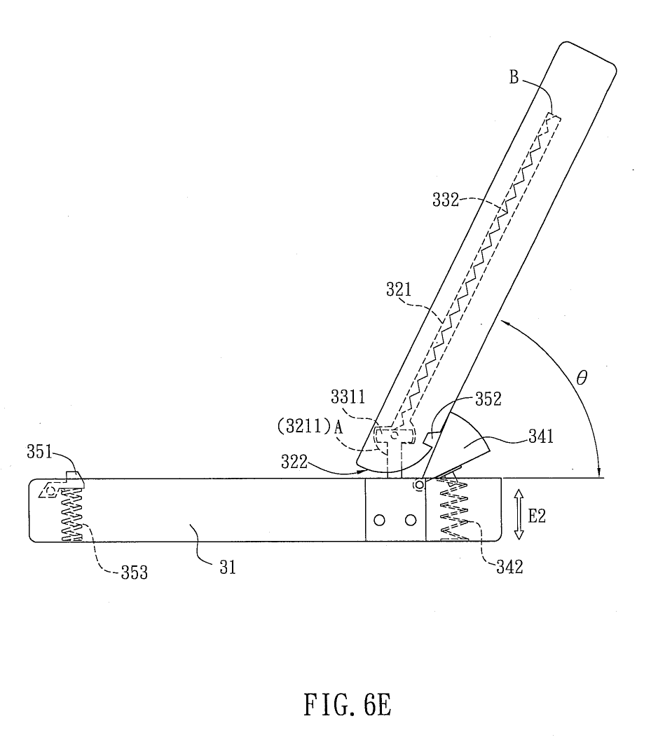

As shown in FIG. 6A to FIG. 6E, to make the feature of the embodiment more obviously, the method for operating the portable electronic device 3 of the preferred embodiment of the invention is illustrated.

As shown in FIG. 6A, the portable electronic device 3 is in a closed state. The first clipping part 351 and the second clipping part 352 of the clipping assembly 35 are fastened to each other. Thus, the first body 31 and the second body 32 abut against each other, and the first elastic part 332 and the second elastic part 342 are compressed. The guiding portion 3311 abuts against the second end B of the first body 31 via the first elastic part 332, and the auxiliary part 341 abuts against the first body 31 via the second elastic part 342.

As shown in FIG. 6B and FIG. 6C, when a user applies a force F1 along a horizontal direction to the second body 32 of the portable electronic device 3 to separate the first clipping part 351 from the second clipping part 352, the first elastic part 332 generates resilience E1 correspondingly to the guiding part 331 after it is not compressed anymore. Thus, the second body 32 slides along the groove 321 relatively to the first body 31 until the first elastic part 332 restores to the uncompressed state. At that moment, the guiding portion 3311 of the guiding part 331 abuts against the positioning portion 3211 of the groove 321.

As shown in FIG. 6D and FIG. 6E, when the user applies a force F2 along a vertical direction to the second body 32, the guiding angle 322 of the second body 32 allows the second body 32 to rotate relatively to the first body 31 smoothly until the guiding portion 3311 of the guiding part 331 abuts against the fan-shaped edge of the positioning portion 3211 of the groove 321. Since the second body 32 is separated from the first body 31, the compressed second elastic part 342 generates resilience E2 to move the auxiliary part 341 to abut against the second body 32. Thus, an angle 0 is formed between the first body 31 and the second body 32.

To sum up, according to a portable electronic device 3 of the embodiment of the invention, when the second body 32 slides relatively to the first body 31, and the guiding portion 3311 slides to the positioning portion 3211, the second body 32 is capable of rotating relatively to the first body 31, and the guiding portion 3311 is allowed to be fastened in the positioning portion 3211. Thus, the second body 32 stands with an angle relatively to the first body 31. Compared with the conventional technology, the first body 31 and the second body 32 not only can be partly separated from each other in a sliding mode, but also can open relatively to each other to form an angle to fix. Thus, the first body 31 and the second body 32 are allowed to be on different planes, and the portable electronic device accords with ergonomics. The portable electronic device 3 which accords with the ergonomics, is operated easily, and does not occupy large room is provided.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A portable electronic device comprising:
a first body;
a second body disposed adjacently to the first body and having a groove with a positioning portion; and
a guiding assembly having a guiding part fixed at the first body, wherein the guiding part has a guiding portion slidingly disposed at the groove to allow the second body to be capable of sliding relatively to the first body, and when the guiding portion slides to the positioning portion, the second body is capable of rotating relatively to the first body, and the guiding portion is allowed to be fastened in the positioning portion to allow the second body to form an angle relatively to the first body.

2. The portable electronic device according to claim 1, wherein the guiding assembly further comprises:
a first elastic part held in the groove, wherein the positioning portion is disposed at one end of the groove, and the two ends of the first elastic part abut against the guiding portion and the other end of the groove, respectively.

3. The portable electronic device according to claim 1, further comprising:
an elastic assembly disposed at a holding room of the first body and having an auxiliary part and a second elastic part, wherein the auxiliary part abuts against the second body, and the second elastic part is disposed between the auxiliary part and the first body.

4. The portable electronic device according to claim 1, wherein the second body has a guiding angle for allowing the second body to slide relatively to the first body smoothly.

5. The portable electronic device according to claim 1, wherein one of a recess, recessed point, protrudent block, protrudent point, protrudent rib, wedge, tenon, stair-shaped structure and sawtooth structure or any combination thereof is disposed in the positioning portion.

6. The portable electronic device according to claim 1, wherein the positioning portion is a circular recess, a fan-shaped recess or a triangular recess.

7. The portable electronic device according to claim 1, wherein the positioning portion has a recessed structure with a symmetrical shape.

8. The portable electronic device according to claim 7, wherein the recessed structure is a pair of fan-shaped recesses, a pair of semi-circular recesses or a pair of triangular recesses.

9. The portable electronic device according to claim 1, further comprising:
a clipping assembly having a first clipping part and a second clipping part, wherein the first clipping part is disposed at the first body, and the second clipping part is disposed at the second body.

10. The portable electronic device according to claim 9, wherein the first clipping part is a hook or an indentation portion, and the second clipping part is an indentation portion or a hook.

11. The portable electronic device according to claim 9, wherein the clipping assembly further comprises:
a third elastic part disposed between the first body and the first clipping part.

12. The portable electronic device according to claim 1, wherein the portable electronic device is one of a mobile communication device, an ultra mobile personal computer, a personal digital assistant, a notebook, a multimedia player and a handheld game player.
